(19) United States
(12) Patent Application Publication
(10) Pub. No.: US 2007/0068458 A1
(43) Pub. Date: Mar. 29, 2007

(54) RAPID THERMAL PROCESSING TOOL

(76) Inventor: Jung-Che Chen, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/162,797

(22) Filed: Sep. 23, 2005

(51) Int. Cl. C23C 16/00

(52) U.S. Cl. 118/724

(57) ABSTRACT

The present invention relates to a rapid thermal processing tool comprises a housing, a chamber formed inside the housing is able to contain an object for a rapid thermal process, a valve formed on the head of the housing, a transit ring formed inside the chamber for inputting and outputting the object in and out of the chamber from the valve, a front exhaust valve formed on the head of the housing and adjacent to the valve, a delivery valve formed inside the chamber for delivering a vapor into the chamber, and a back exhaust valve formed on the back of the housing.

### BACKGROUND OF THE INVENTION

1. Field of the Invention

The present invention relates to a rapid thermal processing tool, and more particularly, to a rapid thermal processing tool having a front exhaust valve.

2. Description of the Prior Art

The rapid thermal processing tool has become more important in recent years due to the development of larger scale, high density single-wafer processing. This trend is cause by the rapid thermal processing tool's flexibility in product production and the stable manufacture. The traditional furnace has high thermal mass and low uniform, and therefore does not apply in the high density and single-wafer manufacturing process. It is succeeded by the rapid thermal processing tool. Additionally, the rapid thermal processing tool has a low thermal budget.

The rapid thermal processing tool works best for rapid thermal oxidation utilized to grow the thin-dielectric, rapid thermal CVD to handle the amorphous silicon, polysilicon tungsten, silicon dioxide and silicon nitride, ion implantation, crystal recombination and stress concentration smooth after silicidation, reflow of borophospho-silicate glass, and rapid thermal annealing of nitridation.

Recently, most rapid thermal processing tools have an exhaust valve, however, the exhaust valve is located far from the valve and purges the chamber by the delivery valve delivers nitrogen etc., that wastes time and purge air. Please refer to the FIG. 1. FIG. 1 is schematic diagram of the conventional thermal processing tool structure. The rapid thermal processing tool 100 has a housing enclosure 124 to cover the inner chamber 118 and the valve 102. When the wafer 116 enters the rapid thermal processing tool 100 (e.g., for the thermal processing process), the valve 102 must open allowing the wafer 116 to enter. In general, the valve 102 opens after the exhaust valve 106 closes. This is necessary because if the exhaust valve 106 is open at this time then too much air will enter into the chamber 118. The air will affect the rapid thermal processing tool's processing of the wafer. The outcome will include: unnecessary impurities in the product and a decrease in the product yield. It is for these reasons that the exhaust valve 106 must close when the valve 102 opens. After the wafer 116 has entered the chamber 118, the exhaust valve 106 will open.

When the wafer 116 is put upon the quartz pin 114, the guide ring 112 will deliver the wafer 116 to the fit position. At this point, the delivery valve 104 will put much of the vapor like the nitrogen and argon into the chamber 118. The oxygen and impurities will be purged in the chamber 118. The nitrogen and argon are controlled by a control valve (not shown) to control the flow rate and the chamber 118 is retained the constant pressure by the exhaust valve 106. Otherwise, the chamber 118 has the oxygen sensor 122 to measure the oxygen concentration in the chamber 118 accurately, and when the oxygen concentration decreases to acceptable concentration, the delivery valve 104 will stop pouring nitrogen and argon and the exhaust valve 106 will close. Next, the wafer is heated rapidly by the lamp 108 for RTO, RT CVD and RTA etc. The pyrometer 120 of the chamber 118 inspects the temperature. After finishing the process, the wafer 116 outputs form the chamber 118.

Please refer to FIG. 2. FIG. 2 is a schematic diagram of the oxygen concentration of the chamber 118 after the valve 102 opens. When the valve 102 is open, the oxygen concentration of the chamber 118 will rise up to D1 in period T1. The rapid thermal processing tool 100 will purge the oxygen (i.e., exhaust the oxygen) that is in the chamber 118 by the utilization of the delivery valve 104 and the exhaust valve 106. After T3, the chamber's 118 oxygen concentration will decrease to an acceptable concentration level for starting the process.

In the other words, the air management system of the conventional rapid thermal processing tool 100 exists the variations of high unnecessary air concentration in the chamber 118 and long retention period of unnecessary air, which wastes great nitrogen and argon to purge the oxygen in the chamber 118. It wastes time and materials in the manufacture process and causes the unstable manufacture quality to affect product yield and yield rate. For this reason, it is importance to find a rapid thermal processing tool to solve the above-mentioned problems.

### SUMMARY OF THE INVENTION

The present invention relates to a rapid thermal processing tool, and more particularly, to a rapid thermal processing tool having a slit exhaust valve.

According to the claimed invention, the rapid thermal processing tool comprises a housing, a chamber formed inside the house is able to contain an object for a rapid thermal process, a valve formed on the head of the housing, a transit ring formed inside the chamber for inputting and outputting the object into the chamber from the valve, a front exhaust valve formed on the head of the housing and adjacent to the valve, a delivery valve formed inside the chamber for delivering a vapor into the chamber, and a back exhaust valve formed on the back of the housing.

The rapid thermal processing tool, according to the present invention, has a front exhaust valve adjacent to the valve itself to rapidly output the air as it exits form the valve and the delivery valve for injecting the nitrogen and argon. Therefore, the present invention resolves the defect of the air management system in the prior art by decreasing the time needed to purge the oxygen and inject the nitrogen and argon into the chamber.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of the conventional thermal processing tool structure.

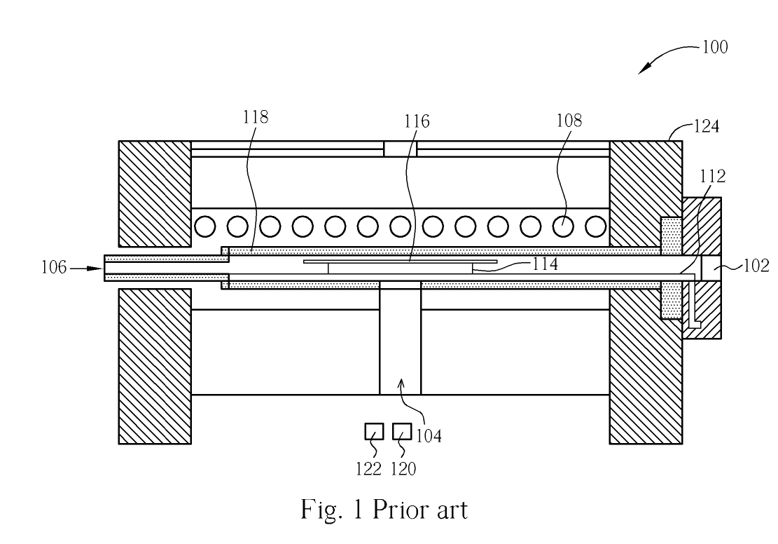

FIG. 2 is a schematic diagram of the oxygen concentration level in the chamber after the valve opens.

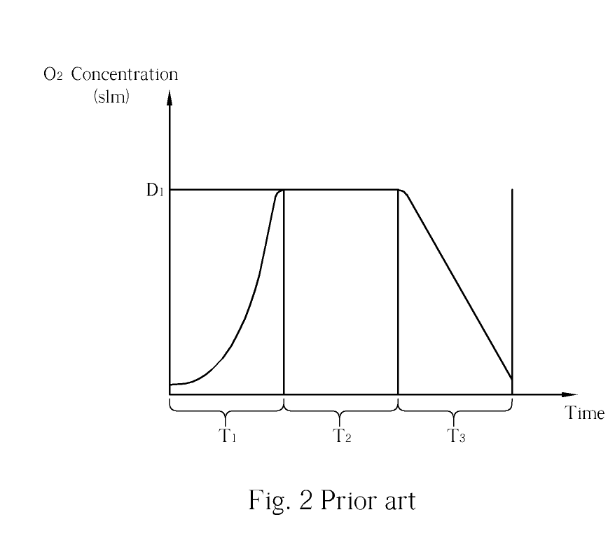

FIG. 3 is a schematic diagram of the rapid thermal processing tool structure according to the present invention.

FIG. 4 is a schematic diagram showing the oxygen concentration level changing in the chamber after the valve opens.

FIG. 5 is a schematic diagram of barrier layer manufacture.

### DETAILED DESCRIPTION

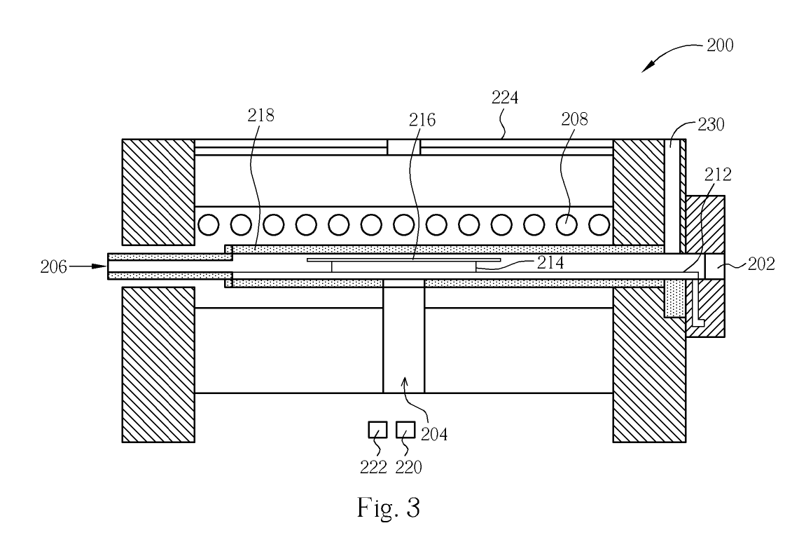

Please refer to FIG. 3. FIG. 3 is a schematic diagram of the rapid thermal processing tool structure according to the present invention. The rapid thermal processing tool 200 according to the present invention has a housing enclosure 224 to cover the inner chamber 228. The valve 202 is formed on the top of the housing enclosure 224, the front exhaust valve 230 is formed adjacent to the valve 202 and the transit ring comprises the guide ring 212 and the quartz pin 214 inside the chamber 218. When the object like the wafer 226 enters the rapid thermal processing tool 200 (e.g., for the thermal processing), the front exhaust valve 230 will open and the delivery valve 204 formed on the central bottom area of the chamber 218 will open at the same time. The delivery valve 204 purges vapor like nitrogen and argon to balance the pressure of the chamber 218. Next, then the valve 202 will open allowing the wafer 226 into the chamber 218.

Because the front exhaust valve 230 is located adjacent to the valve 202, the rapid thermal processing tool 200 reduces any disturbance flow caused by the opening of the valve 202. In comparison to the conventional tool, the present invention will be capable of decreasing the time needed for the front exhaust valve 230 to exhaust air from the chamber 218. The delivery valve 204 delivers nitrogen and argon into the chamber 218 such that air cannot enter the chamber 218 deeply. Because of the front exhaust valve 230 exhausts air out from the chamber 218 and the delivery valve 204 delivers nitrogen and argon into the chamber 218 that balances the pressure of the chamber 218. The oxygen concentration in the chamber 218 of the present invention changes slightly.

After the wafer 216 enters the chamber 218, the valve 202 closes. The rapid thermal processing tool 200 closes the front exhaust valve 230 and opens the back exhaust valve 206 formed on the back of the housing enclosure 224. At the same time, the delivery valve 204 continues purges nitrogen and argon and the wafer 216 is delivered into the fit position by the quartz pin 214 of the guide ring 212. Next, the oxygen sensor 222 in the chamber 218 in the present invention inspects the oxygen concentration level of the rapid thermal processing tool 200. When the concentration level is below the standard level, the nitrogen and argon input flow will cease and the back exhaust valve 206 will close. The air comes firstly into the chamber 218 is exhausted by the front exhaust valve 230. Even, the present invention opens the delivery valve 204 and the back exhaust valve 206 in next process like the prior art, the oxygen concentration of the chamber 218 decreases quickly and the effect is better. Next, the wafer 216 will be heated rapidly by the lamp 208 for RTO, RT CVD, RTA, and so on. The pyrometer 220 in the chamber 218 will inspect the temperature change. Once this process is completed, the wafer 216 will be removed utilizing the valve 202 of the chamber 218.

Please note, the chamber 218 of the rapid thermal processing tool 200 is not a closed space. The space could exist by a combined upper wall and lower wall. And the cracks exist on the walls. The cracks could deliver air and replace the opens of the valve 230, 206 and 214. Otherwise, the lamp 208 of the tool could select form one of the tungsten halogen lamp, arc lamp, resistive heater and the combination of them. The lamp 208 could be formed on the upper house or the lower house or both of them, it dependences on the need of the semiconductor process. Even the temperature and the purge air could be changed dependences on the process.

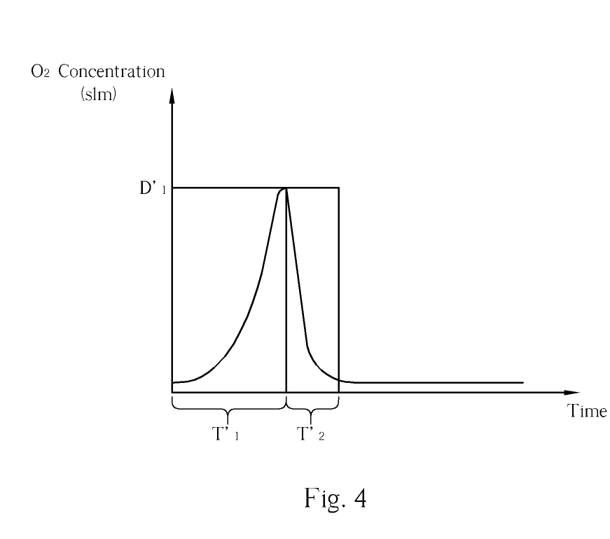

Please refer to FIG. 4. FIG. 4 is a schematic diagram of the oxygen concentration level in the chamber changes after the valve opens. When the valve 202 opens and the wafer 216 enters the chamber 218 through the guide ring 212, the oxygen concentration in the chamber 218 will rise up to D1 in period T1. Because of the front exhaust valve 230 of the rapid thermal processing tool 200 according to the present invention exhausts great air form the chamber 218 and the delivery valve 204 delivers purge air to decreases the disturbance flow, the oxygen comes into the chamber 218 will exhaust out during short T′2. The time (T′1+T′2)of purging the oxygen in the chamber 218 in the present invention is shorter than the time (T1+T2+T3 ) in the prior art. And the oxygen concentration D′1 in the present invention is lower than D1 in the prior art.

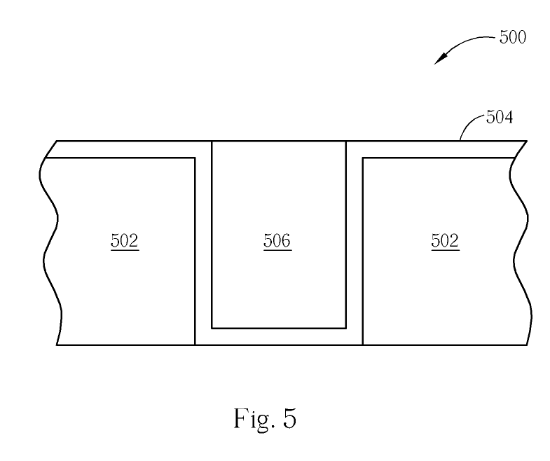

The ability of the rapid thermal processing tool of the present invention to exhaust the oxygen in the chamber make this tool applies for non-oxygen thin film deposition etc. in the semiconductor process. Please refer to FIG. 5. FIG. 5 is a schematic diagram of a barrier layer manufacture. In the process of barrier layer manufacture, the barrier layer 504 is formed on the silicon oxide 502 by etching the contact holes on the dielectric silicon oxide 502 on the surface of the wafer 500.Titanium is sputtered on the wafer 500 around the nitrogen, nitrides to TiN in high temperature. We also can use the responsive sputter process to form the barrier layer 504, TiN on the surface of the wafer 500. After finishing the barrier layer 504 on the wafer 500, the wafer is inputs in the rapid thermal processing tool 200 for RTA. In the same way, the front exhaust valve 230 opens and the delivery valve 204 opens to delivery nitrogen and argon to balance the pressure in the chamber 218. Next, the valve 202 opens and the wafer 500 inputs into the chamber 218 by the guide ring 212. As the above-mentioned, the disturbance flow is exhausted by the front exhaust valve 208, and the delivery valve 204 opens and the air can't come deeply in the chamber 218. After the valve 202 closes, the front exhaust valve 230 closes and the back exhaust valve 206 formed on the back of the house 224 opens. When the oxygen sensor 222 inspects the concentration of the chamber 218 is fit, the lamp 208 will process the rapid thermal processing. The tungsten deposition and CMP etc. are known well by the prior art and no more description.

Compared with the prior art, the rapid thermal processing tool, according to the present invention, has a front exhaust valve adjacent to the valve itself to rapidly output the air as it exits form the valve and a delivery valve for inputting the nitrogen and argon. Therefore, the present invention resolves the defect of the air management system in the prior art by decreasing the time needed to purge the oxygen and to introduce the nitrogen and argon in the chamber.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A rapid thermal processing tool comprising:
a housing;
a chamber formed inside the housing is able to contain an object for a rapid thermal process;
a valve formed on the head of the housing;
a transit ring formed inside the chamber for inputting and outputting the object into the chamber from the valve;
a front exhaust valve formed on the head of the housing and adjacent to the valve;
a delivery valve formed inside the chamber for delivering a vapor into the chamber; and
a back exhaust valve formed on the back of the housing.

2. The rapid thermal processing tool of claim 1, wherein the rapid thermal process comprises rapid thermal oxidation, rapid thermal CVD, and rapid thermal annealing.

3. The rapid thermal processing tool of claim 1, wherein the object is a wafer.

4. The rapid thermal processing tool of claim 3, the transit ring comprises a quartz pin and a guard ring.

5. The rapid thermal processing tool of claim 1, wherein the valve opens as the object is inputted into and outputted from the chamber.

6. The rapid thermal processing tool of claim 5, wherein the delivery valve delivers the vapor into the chamber, the front exhaust valve opens to exhaust the air inside the chamber and the back exhaust valve closes before the valve opens to input the object into the chamber.

7. The rapid thermal processing tool of claim 6, wherein the delivery valve delivers the vapor into the chamber, the back exhaust valve closes and the front exhaust valve opens to exhaust the air that was introduced into the chamber when the object is inputted into the chamber.

8. The rapid thermal processing tool of claim 6, wherein the vapor comprises nitrogen and argon.

9. The rapid thermal processing tool of claim 8, wherein the delivery valve delivers the vapor into the chamber, the front exhaust valve closes and the back exhaust valve opens to exhaust the air inside the chamber when the object is inputted into the chamber and the valve closes.

10. The rapid thermal processing tool of claim 1, wherein the rapid thermal processing tool further comprises a lamp for changing the temperature of the chamber to facilitate the rapid thermal process.

11. The rapid thermal processing tool of claim 1, wherein the rapid thermal processing tool further comprises a pyrometer for measuring the temperature of the chamber.

12. The rapid thermal processing tool of claim 1, wherein the rapid thermal processing tool further comprises an Oxygen density sensor for measuring the oxygen concentration level.
